(19) United States
(12) Patent Application Publication
(10) Pub. No.: US 2014/0218043 A1
(43) Pub. Date: Aug. 7, 2014

(54) ABNORMALITY DETECTION CIRCUIT FOR ELECTRIC STORAGE UNIT AND ABNORMALITY DETECTING METHOD FOR ELECTRIC STORAGE UNIT

(71) Applicant: Kazuya Tsuchiya, Nisshin-shi (JP)

(72) Inventor: Kazuya Tsuchiya, Nisshin-shi (JP)

(73) Assignee: TOYOTA JIDOSHA KABUSHIKI KAISHA, Toyota-shi, Aichi-ken (JP)

(21) Appl. No.: 14/346,101

(22) PCT Filed: Sep. 6, 2012
(86) PCT No.: PCT/IB2012/001718

§ 371 Date: Mar. 20, 2014

(30) Foreign Application Priority Data
Sep. 20, 2011 (JP) 2011-204386

(51) Int. Cl. G01R 31/36

(52) U.S. Cl. CPC G01R 31/3658
USPC 324/434

(57) ABSTRACT

A capacitor has modules each consisting of a plurality of capacitor cells stacked together, and a radiator including heat exchange portions connected to a vehicle body at the ground potential is disposed adjacent to the modules. If an electric leakage occurs to any of the capacitor cells, a leakage detection voltage as a potential difference between the potential of the cell under the leakage and the ground potential is correlated with a module voltage, to provide a constant ratio, from which it is determined that the capacitor is in an abnormal condition.

### BACKGROUND OF THE INVENTION

1. Field of the Invention

The invention relates to detection of an abnormality in an electric storage unit, and in particular to abnormality detection circuit and abnormality detecting method for detecting an abnormality, such as an electric leakage, in an electric storage unit having an electric storage device consisting of a stack of a plurality of cells and a cooler.

2. Description of Related Art

In an electrically powered vehicle, such as a hybrid vehicle or an electric vehicle, an electric leakage in an electric storage unit for driving a motor is detected based on electric power consumed when alternating current is applied to the storage unit (see, for example, Japanese Patent Application Publication No. 2006-078449 (JP 2006-078449 A)).

In JP 2006-078449 A, a technology of conducting self-diagnosis of a leakage detector by creating a pseudo leakage condition, and detecting an abnormality when the leakage is not detected in the pseudo leakage condition, is disclosed.

Also, Japanese Patent Application Publication No. 9-274062 (JP 9-274062 A) discloses a leakage detection system in which a leakage detecting unit receives data after a lapse of a given length of time after switching of switches, so as to eliminate measurement errors due to variations in the high-voltage dc power supply voltage caused by the floating capacitance.

In the technology described in JP 2006-078449 A, the leakage detection based on the consumed power is performed in a condition where a high voltage is applied to the electric storage unit; therefore, when the cooling performance of the cooler for cooling the electric storage device is required to be enhanced, the floating capacitance is also increased, and it may become difficult to detect an electric leakage with accuracy.

### SUMMARY OF THE INVENTION

The present invention provides an abnormality detection circuit for an electric storage unit, which is able to accurately detect an electric leakage in the electric storage unit even if it has a high floating capacitance, irrespective of the magnitude of the floating capacitance, and an abnormality detecting method of detecting an abnormality in the electric storage unit.

An abnormality detection circuit according to one aspect of the invention is provided for an electric storage unit having an electric storage device in which a plurality of cells are stacked together, and a cooler disposed adjacent to the electric storage device and connected to a vehicle body held at the ground potential.

The abnormality detection circuit includes a measuring unit that measures a total module voltage between those of the cells which are located in opposite end portions of the electric storage device, and a potential of the cooler, and a calculating unit that obtains the ratio of the total module voltage to the potential of the cooler.

The abnormality detection circuit may further include a determining unit that determine that the electric storage device operates normally when the ratio of the total module voltage to the potential of the cooler is not constant, or not maintained at a given ratio.

The determining unit may determine that an abnormality, such as an electric leakage, occurs to any of the cells when the ratio of the total module voltage to a potential difference between the cooler and the cell in which the leakage occurs is kept at a constant ratio, and there is a correlation between the total module voltage and the potential difference.

According to the invention, the above-indicated ratio is used for detection of an abnormality in the cells of the electric storage device; thus, an electric leakage can be detected even in the electric storage unit having a high floating capacitance between the storage device and the cooler, irrespective of the magnitude of the floating capacitance.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a circuit block diagram simply illustrating an electric storage unit installed on a vehicle, along with an abnormality detection circuit according to one embodiment of the invention;

FIG. 2 is a view showing one example of arrangement of the electric storage unit and other components in the vehicle;

FIG. 3 is a view showing the case where a module on the left-hand side in FIG. 1 is in a normal condition;

FIG. 4 is a view showing the case where the module on the left-hand side in FIG. 1 is in a leakage condition;

FIG. 5 is a waveform diagram showing variations in voltages with time represented by the horizontal axis;

FIG. 6 is a graph indicating the relationship between a module voltage Vml and a leakage detection voltage V1 received from a differential amplifier, with respect to each current, in the case where the electric storage device is in a normal condition;

FIG. 7 is a graph indicating the relationship between the module voltage Vml and the leakage detection voltage V1 received from the differential amplifier, with respect to each current, in the case where the electric storage device is in a leakage condition;

FIG. 8 is a time chart useful for explaining the relationship between the elapsed time T and the total voltage V;

FIG. 9 is a circuit block diagram showing the manner of detecting an abnormality in an electric storage unit alone before installed on the vehicle or during maintenance, by an abnormality detecting method according to one embodiment of the invention; and

FIG. 10 is a flowchart useful for explaining a procedure of detecting an abnormality.

### DETAILED DESCRIPTION OF EMBODIMENTS

One embodiment of the invention will be described in detail with reference to the drawings. In the drawings, the same reference numerals are assigned to the same or corresponding portions or components, which will not be repeatedly explained.

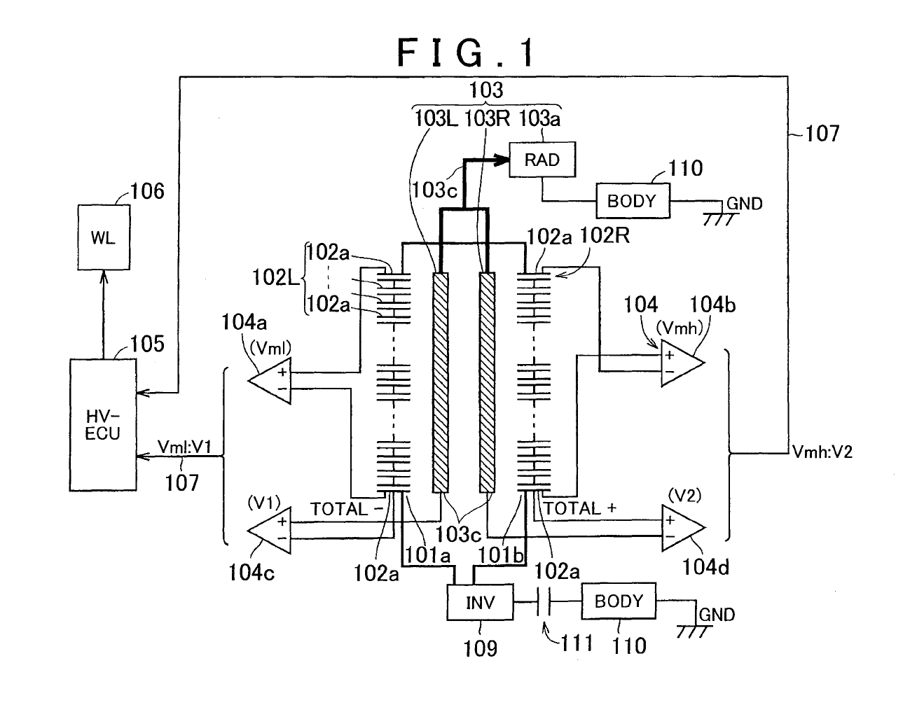

FIG. 1 is a circuit block diagram illustrating an electric storage unit installed on a vehicle 100, along with an abnormality detection circuit according to one embodiment of the invention. In FIG. 1, the electric storage unit is illustrated in a simple form in combination with the configuration of the abnormality detection circuit.

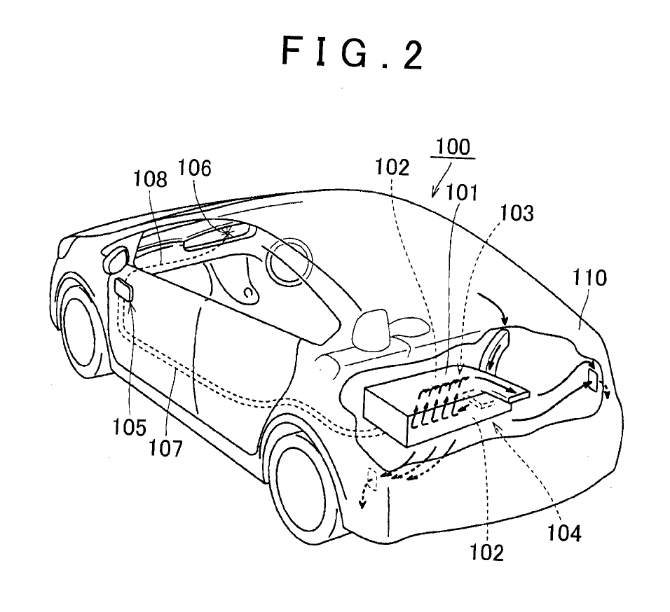

FIG. 2 shows one example of arrangement of the electric storage unit and other components in the vehicle 100. While a capacitor 101 is used as an electric storage device in this embodiment, a high-voltage battery, such as a nickel-metal-hydride battery, or a lithium-ion secondary battery, may be used. The vehicle 100 including the electric storage device, such as an electric double layer capacitor capable of storing electricity, or high-voltage battery as described above, may be used as a hybrid vehicle, or an electric vehicle.

The capacitor 101 mainly consists of modules 102L, 102R, in each of which a plurality of capacitor cells 102a are stacked together and connected in series. In FIG. 1, cooling pipes 103c of a radiator 103 serving as a cooler are inserted through heat exchange portions 103L, 103R for cooling cells, which are placed adjacent to the modules 102L, 102R, and extends in the longitudinal direction between the modules 102L, 102R.

Each of the heat exchange portions 103L, 103R is formed of an aluminum material having electrical conductivity, and is connected to a radiator main body 103a via the corresponding cooling pipe 103c. In operation, cooling water is circulated among the radiator main body 103a and the heat exchange portions 103L, 103R, via the cooling pipes 103c.

Each of the heat exchange portions 103L, 103R is formed integrally with a plurality of cooling fins (not shown) in the form of thin plates made of an aluminum material, such that the cooling fins are arranged at given intervals.

The cooling fins increase the surface area of the heat exchange portions 103L, 103R, and provide a desired amount of heat dissipation by passing air through between the modules 102L, 102R of the capacitor 101, as indicated by arrows in FIG. 2.

The heat exchange portions 103L, 103R may be formed of any other light metal, or an alloy of aluminum and/or other light metals, provided that they are made of an electrically conductive material having high heat conductivity.

The shapes, numbers, and materials of the heat exchange portions 103L, 103R and the cooling pipes 103c may be selected as desired, provided that they provide a large heat dissipation area, and the areas of the heat exchange portions 103L, 103R located adjacent to or contacting the respective capacitor cells 102a of the opposite modules 102L, 102R are large enough to cool the capacitor 101.

Each of the heat exchange portions 103L, 103R of the radiator 103 exchanges heat with a coolant that circulates within the cooling pipe 103c coupled to the radiator main body 103a, and directly dissipates heat into air that passes between the modules 102L, 102R placed adjacent to the heat exchange portions 103L, 103R on the opposite sides thereof, as indicated by arrows in FIG. 2, so that the respective capacitor cells 102a can be cooled with high efficiency.

As shown in FIG. 1, the heat exchange portions 103L, 103R are connected to a vehicle body 110, via the respective cooling pipes 103c, 103c and the radiator main body 103a, so as to be grounded or held at the ground (GND) potential.

An inverter 109 is connected between the opposite (positive and negative) terminals 101a, 101b of the capacitor 101, among the plurality of capacitor cells 102a that constitute the modules 102L, 102R.

The inverter 109 supplies and receives electric power to and from a motor-generator (not shown), and the inverter 109 is connected to the vehicle body 110 or ground to be held at the ground (GND) potential, via a coupling capacitor 111.

Cell terminals of the capacitor cells 102a, 102a located at the opposite ends of each of the modules 102L, 102R that constitute the capacitor 101 are respectively connected to positive input terminal and negative input terminal of a corresponding one of differential amplifiers 104a, 104b for modules, which are provided in a comparison circuit 104 included in the abnormality detection circuit.

Each of the differential amplifiers 104a, 104b for modules detects a module voltage Vml, Vmh representing a voltage applied to the corresponding module 102L, 102R, as a potential difference between the opposite (positive and negative) terminals of the module 102L, 102R as a stack of the capacitor cells 102a.

Each of the modules 102L, 102R consists of 90 insulated capacitor cells 102a of high output type (for example, 6.4 nF/cell), which are connected in series. The capacitor cells 102a are placed adjacent to or in contact with the opposite sides of the heat exchange portions 103L, 103R.

The capacitor cells 102a are stacked together in a direction in which the cooling pipes 103c of the heat exchange portions 103L, 103R extend.

If the modules 102L, 102R are brought closer to the heat exchange portions 103L, 103R, for increase of the contact area between the modules 102L, 102R and the heat exchange portions 103L, 103R, so as to improve the cooling performance, the floating capacitance is further increased, as compared with the case where a lithium-ion secondary battery or a nickel-metal-hydride secondary battery, for example, is used as the secondary battery.

In a known leakage detecting method, it is considered to increase the capacitance of a detection capacitor, or the like, in accordance with the increase in the floating capacitance, so as to improve the detection accuracy. In this case, however, the detection capacitor is increased in size, and requires increased installation space. It is thus difficult to reduce the size of the detection capacitor so that it can be installed on the vehicle.

The differential amplifiers 104a, 104b generate the module voltages Vml; Vmh of the modules 102L, 102R, respectively, to an HV-ECU 105 as a measuring unit.

Furthermore, respective end portions 103d, 103d of the heat exchange portions 103L, 103R and the positive electrode and negative electrode of the capacitor cells 102a, 102a located at the opposite terminals of the capacitor 101, which are connected to the vehicle body 110 via the inverter 109, are respectively connected to positive input terminals and negative input terminals of differential amplifiers 104c, 104d provided in the comparison circuit 104.

When an electric leakage occurs to any of the capacitor cells 102a included in the modules 102L, 102R and connected in series, short-circuit current flows into the heat exchange portion 103L, 103R placed adjacent to the capacitor cell 102a, depending on the position of the capacitor cell 102a.

The differential amplifiers 104c, 104d are connected to the radiator 103 held at the ground (GND) potential, via the respective end portions 103d, 103d of the heat exchange portions 103L, 103R, and generate leakage detection voltages V1, V2, respectively, as a potential difference between the ground (GND) potential of the opposite (positive and negative) terminals 101a, 101b and the potential of the capacitor cell 102a at the shorted position.

The output terminals of the differential amplifiers 104a, 104b for modules and the differential amplifiers 104c, 104d are connected to the HV-ECU 105 as the measuring unit.

The HV-ECU 105 compares the module voltages Vml, Vmh of the respective modules 102L, 102R with the leakage detection voltages V1, V2, respectively, so as to determine whether a constant ratio between the module voltage and the leakage detection voltage is maintained.

When the capacitor 101 is in a normal condition, the leakage detection voltage V1 is not constant, and the ratio of the module voltage Vml to the leakage detection voltage V1 is also not constant. When an electric leakage occurs to one of the capacitor cells 102a of the module 102L, the ratio of the module voltage Vml to the leakage detection voltage V1 is expressed as α:1 (where α is specified by the position of the capacitor cell 102a at which the leakage occurs). By using the relationship between the module voltage and the leakage detection voltage, an electric leakage condition where the above-indicated ratio is stable or constant can be distinguished from a normal condition where the same ratio is not constant, since the voltage obtained by measuring the potential of the cooler is not constant in the normal condition when the floating capacitance is large.

Further, the HV-ECU 105 is connected to a meter illumination control device (not shown). The meter illumination control device has a warning lamp 106 provided in a display of the meter device such that the warning lamp 106 can be visually recognized or viewed from the driver's seat.

The warning lamp 106 may be placed on another portion; such as an upper surface of a capacitor case in which the modules 102L, 102R are housed in the rear part of the vehicle.

Also, the driver or passenger may be informed of an abnormality, through generation of an alarm, notification to the driver, or displaying the number indicating the operating cell position, or the position of the capacitor cell 102a in an abnormal condition, on a monitor screen, for example. Further, a SMR (system main relay) may be disconnected, or control to the fail-safe mode may be performed.

When the HV-ECU 105 determines that each of the leakage detection voltages V1, V2 obtained by measurement is correlated with the corresponding module voltage Vml, Vmh to provide a constant ratio therebetween, and the constant ratio is maintained for a given period of time (a period of 1.0 sec. in this embodiment), the HV-ECU 105 sends an alarm output signal for turning on the warning lamp 106, to the meter illumination control device.

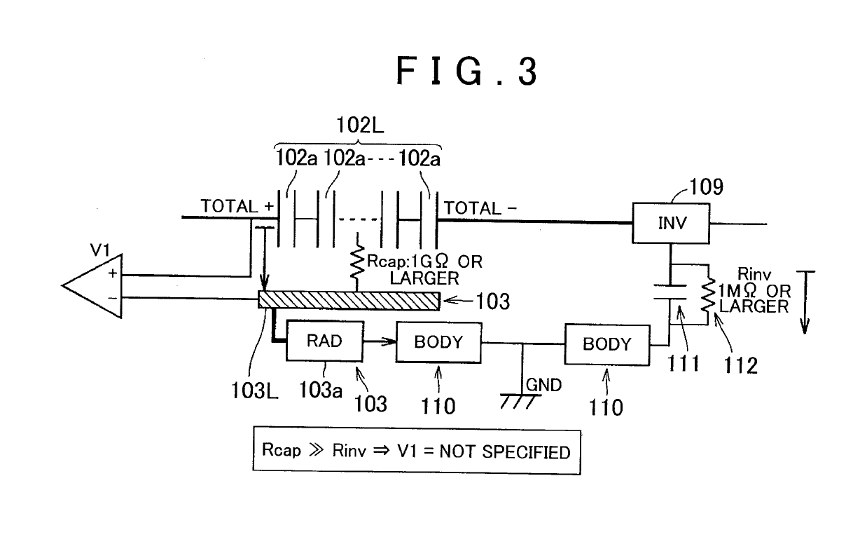

FIG. 3 shows the case where the capacitor 101, in which the module 102L on the left-hand side in FIG. 1 is connected to ground (i.e., is held at the GND potential) via the inverter 109 when installed on the vehicle, is in a normal condition.

The following description about the left-side module 102L also applies to the module 102R on the right-hand side in FIG. 1, which will not be further described.

When the capacitor 101 is in a normal condition, the floating electrostatic capacitance Rcap generated between the module 102L and the heat exchange portion 103L of the radiator 103 is 1 GΩ or larger, and largely exceeds the resistance value, 1MΩ, of a resistor 112 between the vehicle body 110 and the inverter 109; therefore, the leakage detection voltage V1 as an output value of the differential amplifier 104c is not specified.

Here, the leakage detection voltage is not specified when it is not constant and has no correlative relationship with the module voltage, and therefore, cannot be obtained from design or calculation. When the capacitor 101 is mounted on the vehicle, the inconsistent leakage detection voltage further varies with time, depending on disturbances, such as an ambient environment of the vehicle, and/or conditions of use.

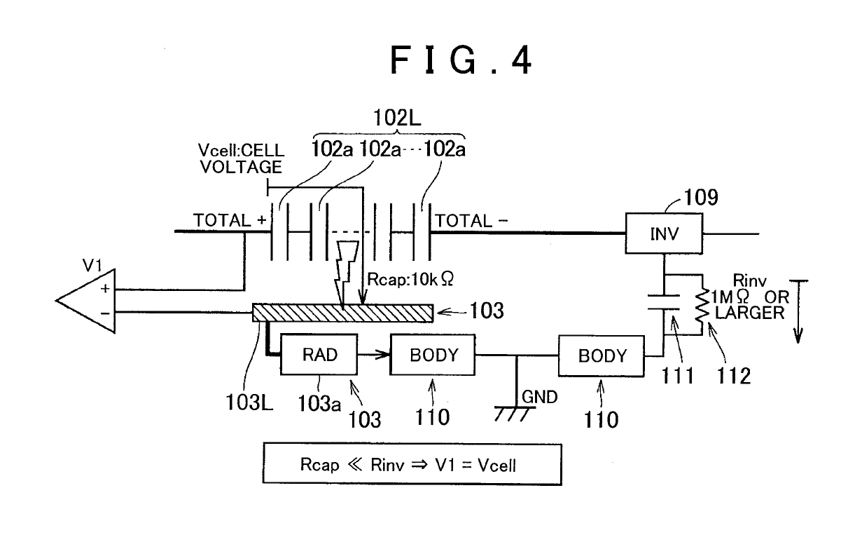

FIG. 4 shows the case where the capacitor 101, in which the module 102L on the left-hand side in FIG. 1 is connected to ground (i.e., is held at the GND potential) via the inverter 109 when installed on the vehicle, is in an electric leakage condition.

In the leakage condition, the module 102L and the heat exchange portion 103L of the radiator 103 are brought into a short-circuit condition, irrespective of the magnitude of the floating electrostatic capacitance Rcap generated between the module 102L and the heat exchange portion 103L. In this case, Rcap becomes equal to about 10 kΩ.

It is known that this resistance value depends on the volume resistivity of a leaking electrolyte, for example. In the short-circuit condition in which the resistance value does not reach the resistance value, 1MΩ, of the resistor 112 between the vehicle body (ground) 110 and the inverter 109, the leakage detection voltage V1 as the output value of the differential amplifier 104c becomes constant, and V1 becomes equal to Vcell representing a difference between the potential of the capacitor cell 102a to which an electric leakage occurs, and that of an end portion connected to the ground (the GND potential).

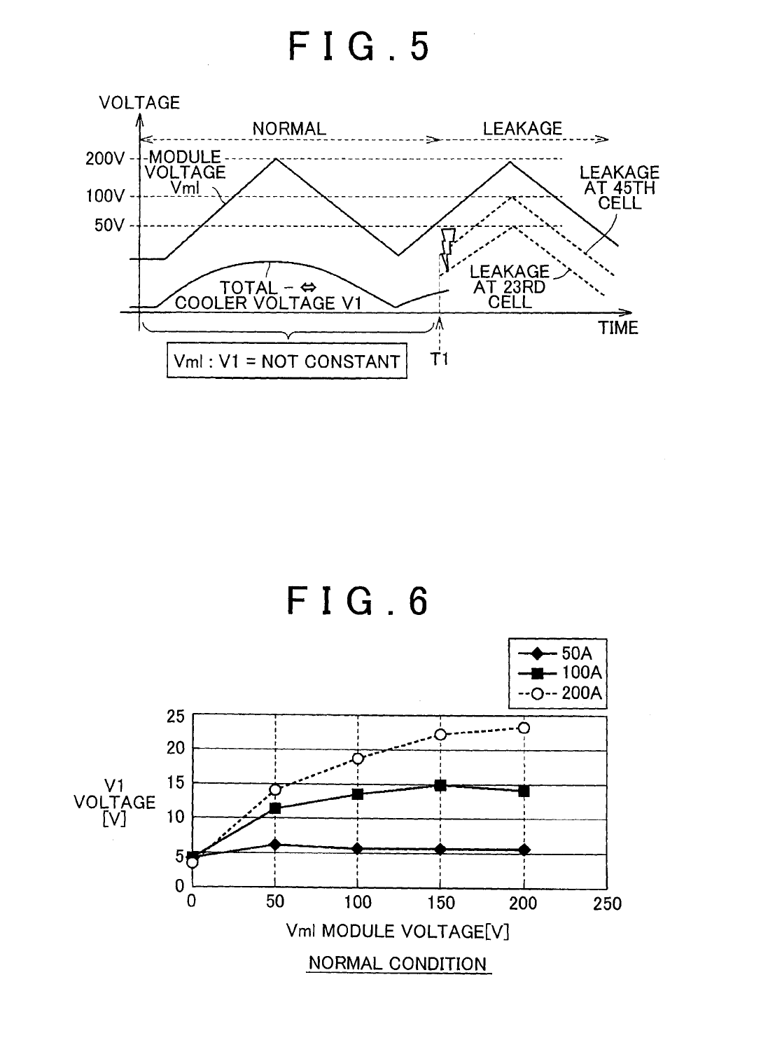

Therefore, the leakage detection voltage V1 as the output value of the differential amplifier 104c is stabilized. FIG. 5 is a waveform diagram showing variations in voltages with time represented by the horizontal axis.

FIG. 5 shows variations in voltages when the capacitor 101 turns from a normal condition into an electric leakage condition at time T1, where current due to CV (constant-voltage) charge, ripple current (having a frequency of 7.5 kHz or 1 kHz, for example), or current having triangular waveform is applied to the capacitor 101.

In FIG. 5, when the capacitor 104 is in a normal condition (i.e., until time T1 is reached), the leakage detection voltage V1 as the output value is not constant and varies with time depending on various conditions, with no regard to variations in the module voltage Vml.

FIG. 6 indicates the relationship between the module voltage Vml and the leakage detection voltage V1 received from the differential amplifier 104c, with respect to each current value.

It is understood from FIG. 6 that, in the normal condition, there is no correlation between the module voltage Vml and the leakage detection voltage V1, at any current value (50 A, 100 A, 200 A), and the leakage detection voltage V1 is not constant.

When the capacitor cell 102a located in a middle portion of the module 102L consisting of 90 capacitor cells 102a undergoes an electric (current) leakage, such as a short-circuit, at time T1 before which the capacitor 101 is in a normal condition as shown in FIG. 5, the leakage detection voltage V1 is stabilized to the potential of the leaking portion (or cell), while being correlated with the module voltage Vml, as indicated by a broken line (labeled as “leakage at 45th cell”) in FIG. 5, upon and after time T1.

When the 23rd capacitor cell 102a, as one of the 90 capacitor cells 102a, undergoes an electric leakage, the leakage detection voltage V1 is reduced as indicated by a thin broken line (labeled as “leakage at 23rd cell”), while being kept correlated with the module voltage Vml.

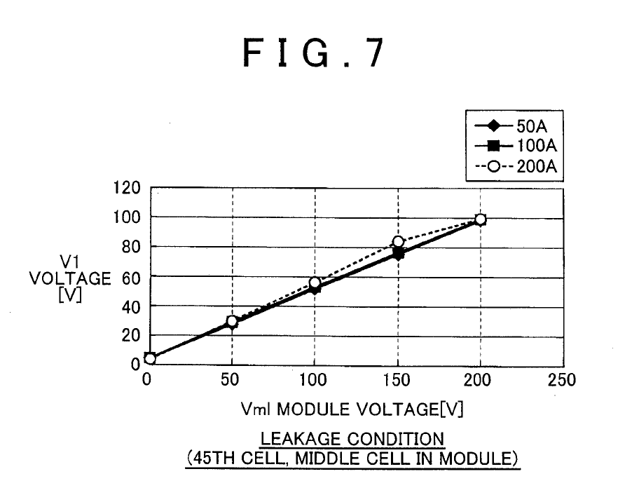

FIG. 7 indicates the relationship between the module voltage Vml and the leakage detection voltage V1 received from the differential amplifier 104c, with respect to each current value.

It is understood from FIG. 7 that when an abnormality, such as an electric leakage or short-circuit, occurs to any one of the capacitor cells 102a, there is a certain correlation similar to a constant proportional relationship between the module voltage Vml and the leakage detection voltage V1, at any current value (50 A, 100 A, 200 A), and a constant voltage ratio is established.

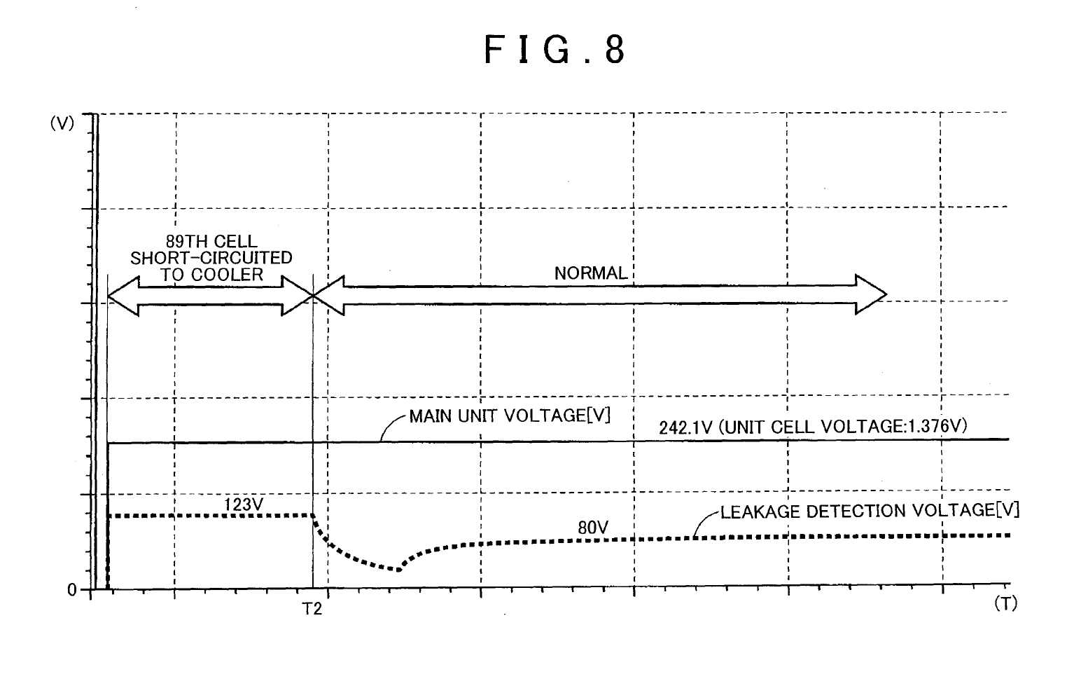

FIG. 8 is a time chart indicating the relationship between the elapsed time T and the total voltage V as a result of a test.

In the test, 176 capacitor cells 102a (each having a unit cell voltage of about 1.376V) are used, and the total voltage V of the main unit is about 240V.

The total module voltage (90 cell×about 1.376V (unit cell voltage)×2 modules 102L, 102R=about 240V) is stably applied between the opposite terminals of the capacitor 101, from time t=0 at which the voltage starts being applied, to time T2 at which the capacitor 101 turns from an electric leakage condition into a normal condition, and after time T2.

Then, a selected one of the capacitor cells 102a (the 89th capacitor cell in this test) is experimentially short-circuited to the heat exchange portion 103L of the radiator 103.

In this case, the leakage detection voltage value is stably held at around 123V (namely, 89 cells×1.346V=about 123V).

In FIG. 8, the short-circuiting is cancelled at time T2 while the total voltage V of the main unit is held at about 240V, so that the capacitor 101 is brought into a normal condition in which no leakage occurs. It is understood from FIG. 8 that the leakage detection voltage is once reduced after time T2, and it takes some time for the voltage to be recovered.

It is understood that the leakage detection voltage (V1, V2) is stabilized with a lapse of time from an abnormal condition to a normal condition, and becomes equal to about 80V after varying unstably, under an experimental environment in which disturbances having an influence on floating charges of the modules 102L, 102R are relatively small, for example, before the capacitor is installed on the vehicle or during maintenance thereof.

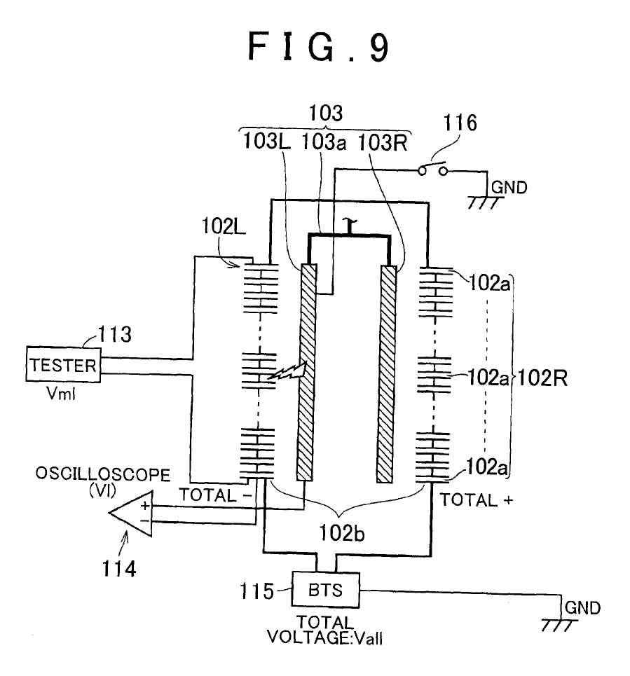

FIG. 9 shows the manner of testing the capacitor 101 alone before it is installed on the vehicle or during maintenance thereof, by the method of detecting an abnormality in the electric storage unit.

The capacitor as an electric storage device is tested in a condition where the modules 102L, 102R as stacks of the capacitor cells 102a and the heat exchange portions 103L, 103R in which parts of the cooling pipe 103c are inserted are assembled together in advance.

In the capacitor 101, the end portions 102b of the modules 102L, 102R and the heat exchange portions 103L, 103R are connected to ground (the GND potential), via a BTS 115 and a switch 116 which are grounded, respectively, in place of the inverter 109 and the radiator main body 103a as shown in FIG. 1.

Then, the module voltage Vml, Vmh between end portions of each module 102L, 102R is detected by means of a tester 113, and the potential of the heat exchange portion 103L is measured using an oscilloscope 114.

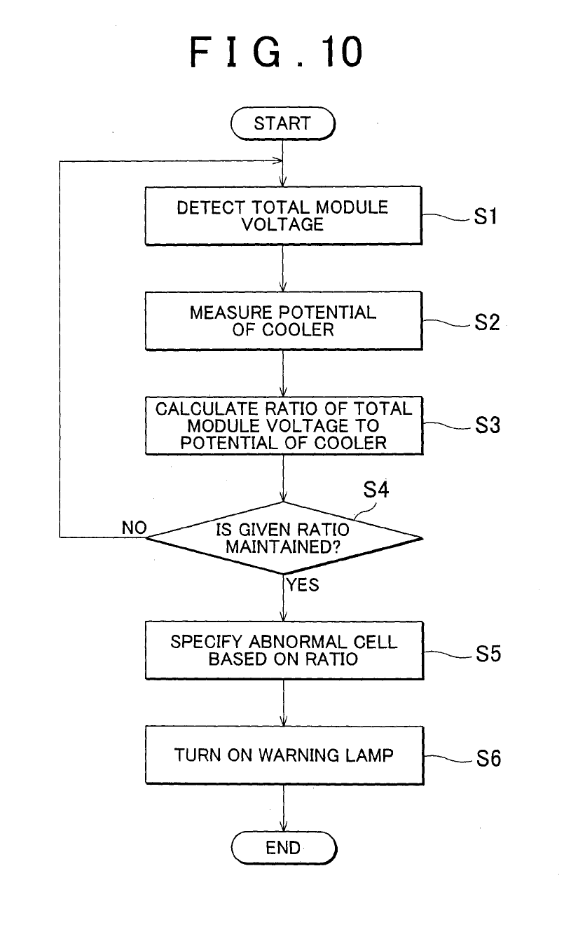

FIG. 10 is a flowchart explaining a procedure of detecting an abnormality.

Referring to the procedure illustrated in the flowchart of FIG. 10, the operation and effects of the abnormality detection circuit for the electric storage unit and the method of detecting an abnormality in the electric storage unit will be described.

Initially, upon start of the abnormality detecting process, the module voltage Vml between the capacitor cells 102a, 102a located at the opposite end portions (positive and negative terminals) of the module 102L on the left-hand side in FIG. 1 is detected in step S1, by means of the differential amplifier 104c.

Also, the module voltage Vmh between the capacitor cells 102a, 102a located at the opposite end portions of the module 102R on the right-hand side in FIG. 1 is detected, by means of the differentia amplifier 104c for module.

Of the detected module voltages Vml, Vmh, the module voltage Vml of the left-side module 102L corresponds to a voltage between the positive and negative terminals of the capacitor cells 102a connected in series, the number of which is obtained by dividing the 90 capacitor cells 102a connected in series, by the number of modules located along the heat exchange portion 103L. The module voltage Vmh of the right-side module 102R corresponds to a voltage between the positive and negative terminals of the capacitor cells 102a connected in series.

In step S2, the potentials of the heat exchange portions 103L, 103R connected to the vehicle body 110 via the radiator main body 103a are measured.

Namely, the potentials of the capacitor cells 102a at the respective end portions of the respective modules 102L, 102R, and the potentials of the respective end portions 103d, 103d of the heat exchange portions 103L, 103R are input to the differential amplifiers 104c, 104d of the heat exchange portions 103L, 103R, respectively.

The differential amplifiers 104c, 104d generate potential differences between the end portions 102a, 102a (the positive and negative terminals) of the modules 102L, 102R connected to ground (the GND potential) and the potentials of the heat exchange portions 103L, 103R, as the leakage detection voltages V1, V2, respectively. The above-described step 1 and step 2 may be executed at the same time, or may be executed in reverse order. Thus, the order of detection and measurement is not limited to that of this embodiment.

In step S3, the HV-ECU 105 as the measuring unit obtains the ratios of the module voltages Vml, Vmh to the leakage detection voltages V1, V2 of the heat exchange portions 103L, 103R, respectively, and uses the thus obtained ratios for detection of an abnormality in the cells.

In step S4, it is determined from the result obtained in step S3 whether a given ratio of the module voltage to the leakage detection voltage is maintained. Thus, if the module voltage Vml obtained from the capacitor cells 102a, 102a located at the opposite end portions of the module 102L is detected, and the leakage detection voltage V1 of the heat exchange portion 103L is measured, the HV-ECU 105 obtains the ratio of these values.

If the ratio of the module voltage Vml, Vmh to the leakage detection voltage V1, V2 is not constant, as shown in a portion of FIG. 5 prior to time T1, it can be determined that there is no correlation between the leakage detection voltage V1, V2 and the module voltage Vml, Vmh, and that the capacitor 101 is operating normally.

In an abnormal condition in which an electric leakage occurs to any of the capacitor cells 102a, the leakage detection voltage V1, V2 generated as a potential difference between the potential of the heat exchange portion 103L connected to the vehicle body 110 (the GND potential) and the potential of the capacitor cell 102a in which the leakage occurs is correlated with the module voltage Vml, Vmh, to provide a constant ratio of the module voltage to the leakage detection voltage.

Therefore, even if the module voltage Vml periodically varies due to current having triangular waveform, as indicated in a portion of FIG. 5 after time T1, the ratio of the module voltage Vml to the leakage detection voltage V1 is maintained at a given value (module voltage Vml:leakage detection voltage V1=α:1, where α is a constant).

If it is determined in step S4 that the given ratio is maintained, the control proceeds to step S5. If the given ratio is not maintained, the control returns to step S1, and detection of an abnormality is continued.

In step S5, the capacitor cell that is in an abnormal condition, such as an electric leakage, is specified, based on the ratio thus measured.

In the specifying step, in the condition in which the given ratio (module voltage Vml:leakage detection voltage V1=α:1, where α is a constant) is maintained even if the module voltage Vml periodically varies due to current having triangular waveform, as indicated in a portion of FIG. 5 after time T1, one of the capacitor cells 102a, as counted from an end portion connected to ground (at the GND potential), in which the abnormality occurs, is specified, based on the value of the constant α.

Further, while the capacitor 101 is not installed on the vehicle as shown in FIG. 9, only the module in which an abnormality occurs is inspected using the tester 113 and the oscilloscope 114, so that the specifying step can be carried out with increased accuracy.

In step S6, an alarm output signal is transmitted from the HV-ECU 105 to the meter illumination control device.

Then, the warning lamp 106 provided in the display of the meter device which can be viewed from the passenger's seat is turned on by the meter illumination control device. With this arrangement, the passenger or driver is informed of which one of the capacitor cells 102a is abnormal or at fault, even during use of the capacitor 101 installed on the vehicle, for example, during running of the vehicle.

Thus, even if the electric storage unit has a high floating capacitance, the abnormality detection circuit for the electric storage unit and the abnormality detecting method for the electric storage unit according to this embodiment make it possible to accurately detect an electric leakage, irrespective of the magnitude of the floating capacitance.

Finally, the embodiment of the invention will be summarized with reference to the drawings. Referring to FIG. 1 and FIG. 2, the vehicle 100 has the capacitor 101 including the modules 102L, 102R in each of which a plurality of capacitor cells 102a are stacked together, and the radiator 103 including the heat exchange portions 103L, 103R placed adjacent to electric storage portions in the form of laminated cells in the capacitor 101 and connected to the vehicle body 110 (at the GND potential).

The vehicle 100 is installed with the abnormality detection circuit for detecting an abnormality in the capacitor 101, or is connected to the abnormality detection circuit provided outside of the vehicle.

Preferably, the module voltage obtained from the capacitor cells 102a located at the opposite end portions of the capacitor 101, and the potential of the radiator 103 are detected or measured, and it can be determined that the capacitor 101 is operating normally if the ratio of these measurement values is not constant.

If an electric leakage occurs to any of the capacitor cells 102a, the leakage detection voltage V1 as a potential difference between the potential of) the radiator 103 connected to the vehicle body 110 (at the GND potential) and the potential of the capacitor cell 102a that suffers from the leakage has a correlative relationship with the module voltage Vml, such that the ratio of the module voltage Vml to the leakage detection voltage V1 is constant, as shown in FIG. 5, and the passenger is informed that the electric storage device is in an abnormal condition.

Preferably, the HV-ECU 105 measures the module voltage Vml, Vmh and the potential of the heat exchange portion 103L, 103R of the radiator 103, and obtains the ratio of the module voltage to the potential of the heat exchange portion, so that the thus obtained ratio can be used for detecting an abnormality in the capacitor cells 102a.

Thus, even if the capacitor 101 has a high floating capacitance, an electric leakage can be accurately detected, irrespective of the magnitude of the floating capacitance between the capacitor 101 and the radiator 103.

Preferably, the HV-ECU 105 can specify which one of the plurality of capacitor cells 102a, as counted from an end portion of the capacitor 101 connected to ground (at the GND potential), suffers from the electric leakage, based on the value of the constant ratio.

The invention is also concerned with the method of detecting an abnormality in the electric storage unit having the capacitor 101 in which a plurality of capacitor cells 102a are stacked together, and the heat exchange portions 103L, 103R of the radiator 103 placed adjacent to the capacitor 101 and connected to ground (at the GND potential).

Referring to FIG. 1 and FIG. 10, the method of detecting an abnormality in the capacitor 101 has step S1 of detecting the module voltage Vml, Vmh obtained from the capacitor cells 102a located at the opposite end portions of the capacitor 101, step S2 of measuring the potential of the heat exchange portion 103L, 103R, and obtaining the leakage detection voltage V1, V2 as a potential difference from the GND potential, step S3 of obtaining the ratio of the module voltage Vml, Vmh to the leakage detection voltage V1, V2 obtained as a potential difference between the potential of the heat exchange portion 103L, 103R and the GND potential, and step S6 of determining that the capacitor 101 is operating within a normal operating range if the ratio of the measurement values obtained by the HV-ECU 105 is not constant, namely, a given ratio of the module voltage Vml, Vmh to the leakage detection voltage V1, V2 is not maintained as the module voltage Vml, Vmh varies, and determining that there is an abnormality in the capacitor 101 if the ratio of the measurement values obtained by the HV-ECU 105 is constant, namely, a given ratio of the module voltage Vml, Vmh to the leakage detection voltage V1, V2 is maintained as the module voltage varies.

Preferably, step S5 is provided for specifying the capacitor cell 102a that is in an abnormal condition, such as a leakage, based on the ratio of the measurement values.

Therefore, even if the electric storage unit has a high floating capacitance, the position of the capacitor cell 102a in which the leakage occurs can be accurately detected, irrespective of the magnitude of the floating capacitance between the capacitor cells 102a and the heat exchange portion 103L of the radiator 103.

Thus, the ratio of the module voltage Vml, Vmh to the leakage detection voltage V1, V2 obtained from the potential of the cooler is obtained, by measuring these values using the HV-ECU 105 installed on the vehicle 100, or the tester 113 and the oscilloscope 114.

Then, it can be determined that the electric storage device is operating normally within a normal operating range, if the ratio of the module voltage Vml, Vmh to the leakage detection voltage V1, V2 is not constant as the module voltage varies, or there is no correlation between the module voltage Vml, Vmh and the leakage detection voltage V1, V2.

If an electric leakage occurs to any of the capacitor cells 102a, the capacitor cell 102a is short-circuited to the radiator 103 disposed adjacent to the capacitor cell 102a and connected to ground (at the GND potential), and the leakage detection voltage V1, V2 of the capacitor cell 102a in which the leakage occurs has a certain correlation with the module voltage Vml, Vmh, such that the ratio of the module voltage Vml, Vmh to the leakage detection voltage V1, V2 is a constant ratio α.

The capacitor 101 may have a high floating capacitance due to its arrangement in which the heat exchange portions 103L, 103R of the radiator 103 for cooling are interposed between the modules 102L, 102R.

In this case, the voltage detected between the modules 102L, 102R in a normal condition is not constant.

By taking note of the fact that the voltage is not constant in the normal condition as described above, the inventor of the present invention makes use of the fact that there is a correlation, i.e., a constant ratio α, between the leakage detection voltage V1, V2 and the module voltage Vml, Vmh in an abnormal condition in which short-circuit occurs due to an electric leakage.

Thus, the abnormality detection circuit for the electric storage unit and the abnormality detecting method for the electric storage unit are provided which make it possible to accurately detect an electric leakage, irrespective of the total voltage V that is likely to vary due to disturbances, such as an ambient environment of the vehicle, or conditions of use, when the storage unit is mounted on the vehicle. The abnormality detection circuit and detecting method are preferably employed when a high-voltage storage device, such as a high-capacitance capacitor 101, is used in the vehicle.

Further, when the electric storage device is in a normal operating range, the ratio of the module voltage Vml, Vmh to the leakage detection voltage V1, V2 is not constant as the module voltage varies, and there is no correlation between the leakage detection voltage V1, V2 and the module voltage Vml, Vmh. Thus, it can be determined whether the electric storage device is operating normally even while it is mounted on the vehicle.

While the radiator 103 that circulates a coolant in the cooling pipes 103c is used as a cooler in the illustrated embodiment, the cooler is not particularly limited to this type, but a set of a plurality of cooling fins like thin plates may be used for cooling the modules 102L, 102R located adjacent to the fins, by passing air through the cooling fins, for example. Thus, the shape, number and material of components of the cooler are not particularly limited, provided that the cooler is disposed adjacent to the electric storage device. Further, the coolant is not limited to water (fresh water), but an oil cooler, or the like, using a mixed liquid containing a preservative or ethylene glycol, for example, or a lubricant for cooling, may be used.

The vehicle to which the abnormality detection circuit for the electric storage unit and the abnormality detecting method for the electric storage unit according to the invention are applied is not limited to the electrically powered vehicle as illustrated in FIG. 2, but the electric storage unit to which the invention is applied may be used in other types of vehicles, such as a hybrid vehicle and an electric vehicle, which use the storage unit as a power source. In addition, the electric storage unit to which the invention is applied may be used along with a power source for other vehicle-mounted electrical equipment, or as a dedicated power supply, or may be used as a part of household power supplies.

It is to be understood that all points of the illustrated embodiment are merely exemplary, and not limiting. The scope of the invention is not limited to the above description of the embodiment but is defined by the appended claims, and is intended to include all changes or modifications within the scope of the invention defined by the appended claims and equivalents thereof.

1. An abnormality detection system comprising:
an electric storage unit including an electric storage device in which a plurality of cells are stacked together, and a cooler disposed adjacent to the electric storage device and connected to ground;
an electric control unit configured to measure a total module voltage between the cells of the plurality of cells which are located in opposite end portions of the electric storage device, and a potential of the cooler; and
the electric control unit configured to obtain a ratio of the total module voltage to the potential of the cooler.

2. The abnormality detection system according to claim 1, wherein:
the electric control unit is configured to determine that the electric storage device operates within a normal operating range, when the ratio of the total module voltage to the potential of the cooler is not maintained at a given ratio as the total module voltage varies, and there is no correlation between the total module voltage and the potential of the cooler.

3. The abnormality detection system according to claim 1, wherein:
the electric control unit is configured to determine that there is an abnormality in the electric storage device, when the ratio of the total module voltage to the potential of the cooler is kept at a constant ratio as the total module voltage varies, and there is a correlation between the total module voltage and the potential of the cooler.

4. The abnormality detection system according to claim 3, wherein the electric control unit is configured to specify one of the plurality of cells in which an electric leakage occurs, as counted from a grounded end portion of the electric storage device, based on a value of the constant ratio.

5. An abnormality detecting method of detecting an abnormality in an electric storage unit having an electric storage device in which a plurality of cells are stacked together, and a cooler disposed adjacent to the electric storage device and connected to ground, the abnormality detecting method comprising:
detecting a total module voltage between the cells of the plurality of cells which are located in opposite end portions of the electric storage device;
measuring a potential of the cooler;
obtaining a ratio of the total module voltage to the potential of the cooler;
determining that the electric storage device operates within a normal operating range when the ratio of the total module voltage to the potential of the cooler is not maintained at a given ratio as the module voltage varies, and there is no correlation between the total module voltage and the potential of the cooler; and
determining that there is an abnormality in the electric storage device, when the ratio of the total module voltage to the potential of the cooler is kept at a constant ratio as the total module voltage varies, and there is the correlation between the total module voltage and the potential of the cooler.

6. The abnormality detecting method according to claim 5, further comprising:
specifying one of the plurality of cells in which an electric leakage occurs, as counted from a grounded end portion of the electric storage device, based on a value of the constant ratio.
